(19) United States
(12) Patent Application Publication
(10) Pub. No.: US 2012/0134085 A1
(43) Pub. Date: May 31, 2012

(54) SERVER INTEGRATING SYSTEM

(75) Inventors: Hsing-Chao GAU, TAIPEI CITY (TW); Huang-Ching WANG, TAIPEI CITY (TW); Chien-Chuan HUANG, TAIPEI CITY (TW)

(73) Assignee: INVENTEC CORPORATION, TAIPEI CITY (TW)

(21) Appl. No.: 12/981,503

(22) Filed: Dec. 30, 2010

(30) Foreign Application Priority Data
Nov. 30, 2010 (TW) 099141488

(51) Int. Cl. H05K 7/00

(52) U.S. Cl. 361/679.02

(57) ABSTRACT

A server integrating system contains at least one rack, and the rack contains servers and a rack management board. The rack management board is connected to the chassis management board through a transmission line, in which the chassis management board sends the information of the servers to the rack management board, and the chassis management board passes the data to the rack management board.

### RELATED APPLICATIONS

This application claims priority to Taiwan Application Serial Number 099141488, filed Nov. 30, 2010, which is herein incorporated by reference.

### BACKGROUND

1. Field of Invention

The present invention relates to a server. More particularly, the present invention relates to a server integrating system.

2. Description of Related Art

With the fast changing of the electronic technology, the assembling of an electronic device such as a computer, a server and so on, becomes more and more precise. Therefore, it is already an obvious focus of attention in this field how to effectively improve a work efficiency to meet a maximum economic benefit. Taking a server as an example, in addition to a motherboard, the server has a storage device for storing mass data, such as a hard disk driver, a floppy disk driver and an optical disc driver used for reading external data, etc. In order to satisfy the strong computation requirements of the server system, e.g. in order to increase the computation speed and reliable computation time and enhance the external data output and input capabilities, a large server system usually has two or more servers to improve the performance.

However, in order to manage so many servers, connection lines need to be provided for different functions. In the course of monitoring, perhaps a confirmation needs to be made for the servers one by one, so lots of manpower and time are wasted. Furthermore, when several servers on a rack are powered on, the power system may be overloaded due to an instant boot over-current if the servers are booted simultaneously. When the servers enter a standby state, the power supply still needs to be adjusted so as to save power. Therefore, there is a need for a new system to manage a large number of servers properly.

### SUMMARY

According to an embodiment of the present invention, a server integrating system integrates several servers on a rack. The server integrating system contains a rack, and the rack includes a plurality of servers, a rack management board (RMB) and a chassis network switch. The rack management board collects and manages an operation state of the servers, and the chassis network switch is electrically connected between the servers and the rack management board so as to pass an instruction and data between the servers and the rack management board. The server further includes a chassis management board (CMB) for collecting and passing data of the servers and receiving an instruction and data sent by the rack management board.

In another embodiment, the server integrating system includes a plurality of racks and a rack network switch, and the rack management boards of all the racks are connected to each other through a rack network switch to pass a message and an instruction.

The server integrating system in the above embodiments can perform a centralized control and management of several servers and even several racks, and can monitor a use state of each server and adjust a power supply state of each server according to the user state of each server, so as to save the power and ensure the stability of the power supply.

### BRIEF DESCRIPTION OF THE DRAWINGS

In order to make the foregoing as well as other aspects, features, advantages, and embodiments of the present invention more apparent, the accompanying drawings are described as follows:

FIG. 1 is a block diagram of a server integrating system according to an embodiment of the present invention; and

FIG. 2 is a block diagram of a server integrating system according to another embodiment of the present invention.

### DETAILED DESCRIPTION

The server integrating system in the following embodiments can accommodate several server systems collectively so as to reduce a space occupied by the accommodated servers. Also, the server integrating system can monitor a use state of each server and adjust a power supply state of each server according to the use state of each server, thereby avoiding the idleness of the servers so as not to cause a waste of power.

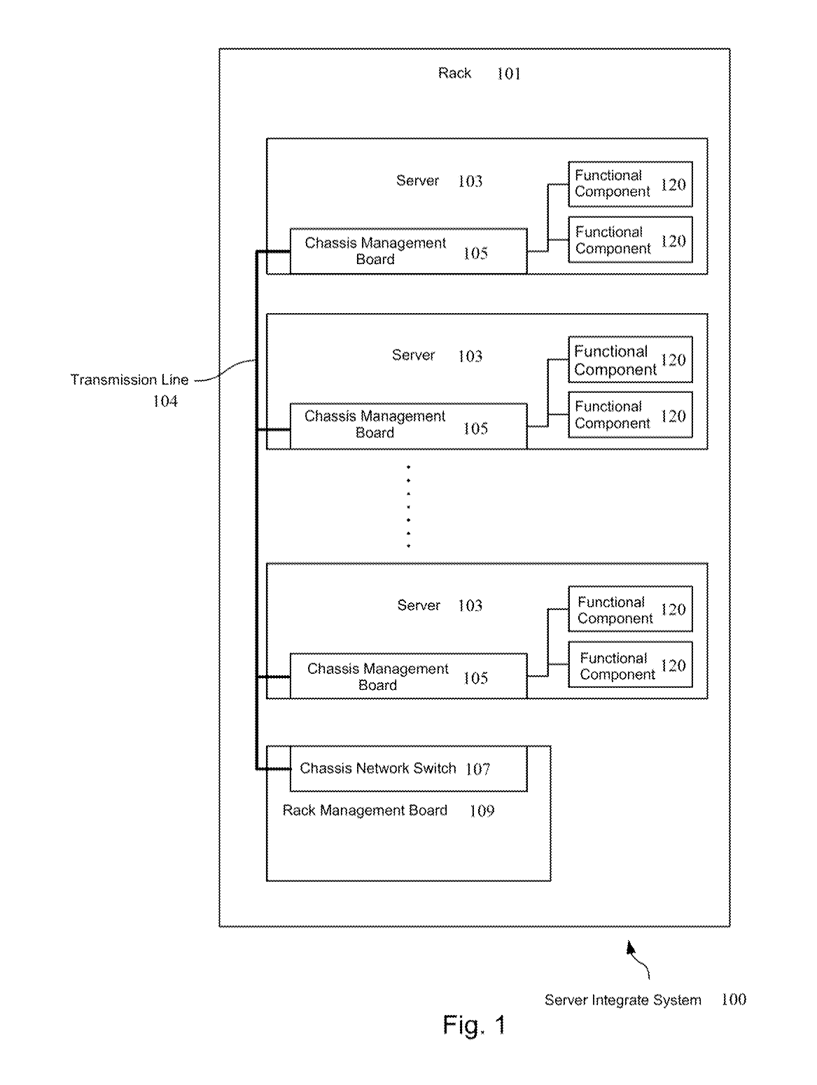

Referring to FIG. 1, FIG. 1 is a block diagram of a server integrating system according to an embodiment of the present invention. The server integrating system 100 integrates several servers 103, and the server integrating system 100 contains a rack 101, a plurality of servers 103 and a rack management board 109. Each server 103 has a chassis management board 105. In this embodiment, the chassis management board 105 integrates signals transmitted by each server 103 to a functional component 120. The functional component 120 may be a sensor, and the sensor is electrically connected to the chassis management board 105 to detect an ambient temperature. The functional component 120 may also be a power module, and the power module is controlled by the chassis management board 105 to provide power to a motherboard (not shown) on the server. The functional component 120 may also be a fan module electrically connected to the chassis management board 105. A rotation speed of the fan module is controlled by the chassis management board 105 so that the fan module produces an air flow to decrease the ambient temperature.

The functional component 120 may further be a hard disk backplane. The hard disk backplane is adapted between the chassis management board 105 and several hard drives (not shown), so that the chassis management board 105 or the motherboard can control and manage the hard disks. The hard disk backplane can be provided with several slave microcontrollers thereon, and the slave microcontrollers can decode a message passed by a hard disk controller/hard disk.

In order to be connected to a variety of functional components 120, the chassis management board 105 may include a keyboard controller style (KCS) interface, an inter-integrated circuit (12C) interface, a universal asynchronous receiver/transmitter (UART) interface, a serial peripheral interface (SPI), a general purpose I/O (GPIO) interface, a universal serial bus (USB) interface or a local area network (LAN) interface.

The rack management board 109 has a chassis network switch 107 so as to be connected to each chassis management board 105. The chassis management board 105 collects a state and relevant data of the corresponding server 103 and sends them to the rack management board 109. A system administrator can know the state of each server on the rack 101 through the rack management board 109. The rack management board 109 can also manage a power supply according to the obtained data.

For example, usually, the system administrator must log in to each server 103 to find out whether there is something wrong with the states of the servers. However, by using the present invention, the system administrator can know the states of the servers on the rack 101 just through the rack management board 109. In practice, the rack management board 109 may be a circuit board disposed on the rack 101 and may also be a computer with simplified functions. When the rack management board 109 knows that a certain server 103 enters an idle state or a standby state, the rack management board 109 reduces the power provided to the server 103 so as to save the power. In contrast, when a certain server 103 operates completely, the chassis management board 105 can assign more power to this server 103. The chassis management board 105 and the chassis network switch 107 pass a message to each other through a transmission line 104, and the transmission line 104 is a network cable, so the rack 101 can achieve an effect without need of a complicated circuit.

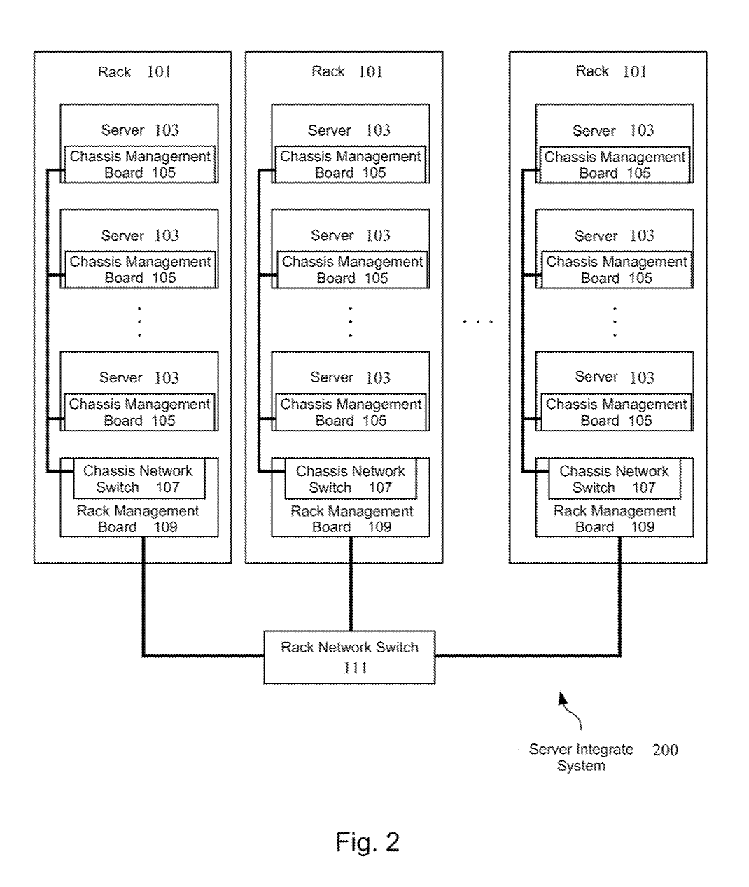

Referring to FIG. 2, FIG. 2 is a block diagram of a server integrating system according to another embodiment of the present invention. In this embodiment, the server integrating system 200 includes a plurality of racks 101 and a rack network switch 111. Each rack management board 109 is connected to the rack network switch 111. In this way, the system administrator can know the states of the servers 103 in the entire domain by selecting only one rack management board 109. During power control, a larger range of control can be achieved.

The server integrating system in the above embodiments can monitor a use state of each server and adjust a power supply state of each server according to the use state of each server, thereby avoiding the idleness of the servers so as not to cause a waste of power. Particularly, during booting, the servers can be controlled to be powered on at an interval of several seconds so as to avoid an instant over-current that may cause the power system to be is overloaded when all the servers are booted simultaneously.

Although the present invention has been disclosed with reference to the above embodiments, these embodiments are not intended to limit the present invention. It will be apparent to those skilled in the art that various modifications and variations can be made without departing from the scope or spirit of the present invention. Therefore, the scope of the present invention shall be defined by the appended claims.

What is claimed is:

1. A server integrating system, comprising:
a rack, comprising:
at least one server, having a chassis management board;
a transmission line; and
a rack management board, connected to the chassis management board through the transmission line,
wherein the chassis management board sends data of the server to the rack management board, and the rack management board sends an instruction and data to the chassis management board.

2. The server integrating system of claim 1, wherein the chassis management board further comprises a chassis network switch, and the transmission line is a network cable and is connected to the chassis network switch.

3. The server integrating system of claim 1, wherein the chassis management board integrates signals transmitted by each server to at least one functional component.

4. The server integrating system of claim 3, wherein the functional component is a sensor electrically connected to the chassis management board, and the sensor detects an ambient temperature.

5. The server integrating system of claim 3, wherein the functional component is a power module, and the power module is controlled by the chassis management board to provide power to the motherboard.

6. The server integrating system of claim 3, wherein the functional component is a fan module electrically connected to the chassis management board, and a rotation speed of the fan module is controlled by the chassis management board so that the fan module produces an air flow to decrease the ambient temperature.

7. A server integrating system, comprising:
a plurality of racks, each of which comprises:
at least one server, having a chassis management board; and
a rack management board, connected to the chassis management board,
wherein the chassis management board sends data of the server to the rack management board, and the rack management board sends an instruction and data to the chassis management board; and
a rack network switch, connected to the chassis management boards.

8. The server integrating system of claim 7, wherein the chassis management board further comprises a chassis network switch, and the transmission line is a network cable and is connected to the chassis network switch.

9. The server integrating system of claim 7, wherein the chassis management board integrates signals transmitted by each server to at least one functional component.

10. The server integrating system of claim 9, wherein the functional component is a sensor, a power module or a fan module.
